(19) United States
(12) Patent Application Publication
(10) Pub. No.: US 2013/0015552 A1
(43) Pub. Date: Jan. 17, 2013

(54) Electrical Isolation Of High Defect Density Regions In A Semiconductor Device

(71) Applicants: Isik C. Kizilyalli, San Francisco, CA (US); David P. Bour, Cupertino, CA (US); Richard J. Brown, Los Gatos, CA (US); Andrew P. Edwards, San Jose, CA (US); Hui Nie, Cupertino, CA (US); Linda T. Romano, Sunnyvale, CA (US)

(72) Inventors: Isik C. Kizilyalli, San Francisco, CA (US); David P. Bour, Cupertino, CA (US); Richard J. Brown, Los Gatos, CA (US); Andrew P. Edwards, San Jose, CA (US); Hui Nie, Cupertino, CA (US); Linda T. Romano, Sunnyvale, CA (US)

(73) Assignee: EPOWERSOFT, INC., San Jose, CA (US)

(21) Appl. No.: 13/180,758

(22) Filed: Jul. 12, 2011

(51) Int. Cl. H01L 29/36; H01L 21/761; H01L 29/06; H01L 21/762

(52) U.S. Cl. 257/506; 257/607; 257/610; 438/424; 438/414; 257/E29.109; 257/E21.546; 257/E21.544; 257/E29.005

(57) ABSTRACT

Embodiments of the invention include a III-nitride semiconductor layer including a first portion having a first defect density and a second portion having a second defect density. The first defect density is greater than the second defect density. An insulating material is disposed over the first portion. The insulating material is not formed on or is removed from the second portion.

### BACKGROUND

III-nitride materials, particularly binary, ternary, quaternary, and quinary alloys of gallium, boron, aluminum, indium, and nitrogen, have been used to produce semiconductor light emitting devices such as light emitting diodes and laser diodes. III-nitride materials may also have advantages for power electronics, particularly in applications requiring high voltage, high power, high temperature, or high frequency operation.

III-nitride materials are typically fabricated by epitaxial growth on a substrate such as sapphire, silicon, silicon carbide, or GaN. N-type layers are typically doped with Si and p-type layers are typically doped with Mg. Examples of suitable epitaxial techniques include metal organic chemical vapor deposition and molecular beam epitaxy. III-nitride devices are often grown on non-III-nitride substrates such as sapphire or silicon due to the low cost and wide availability of sapphire and silicon substrates.

High densities of defects such as dislocations, for example on the order of 10⁹ cm⁻², are produced at the interface between a GaN layer and a sapphire or other non-III-nitride substrates on which the GaN layer is grown, due to the large mismatch between the crystal lattices of the GaN layer and the substrate. The defects tend to propagate throughout the as-grown layers. Because dislocations are not desirable within the active device layer, it is preferable to grow GaN on a GaN substrate, in order to reduce the density of dislocations. III-V substrates besides GaN, such as GaAs and InP, may be formed by melt growth, where the III-V material is melted at high temperature and cooled and solidified below the melting point so that a solid single crystal ingot grows from a small seed crystal. It is not practical to form GaN substrates by melt growth because extremely high temperature and pressure are required to prevent decomposition of the GaN at the melting point. Accordingly, current commercially-available GaN substrates are generally formed by growing a thick GaN layer at a high growth rate on a non-III-nitride substrate by hydride vapor phase epitaxy, then removing the non-III-nitride substrate. A patterned thin layer of a different material from GaN is formed on the non-III-nitride substrate before growth of the thick GaN layer. As the thick GaN layer grows, pits form over the areas of different material on the patterned layer. Dislocations and other defects are concentrated in the pits, leaving the areas between the pits with dislocations densities of 10⁵ cm⁻² or lower. The concentrations of dislocations are referred to herein as defect centers. The patterned layer may be formed such that the defect centers are points or lines.

### SUMMARY

In some devices including defect centers, the defect centers must be electrically isolated from metal contacts or conducting regions in order to avoid shorting.

Embodiments of the invention include a III-nitride semiconductor layer including a first portion having a first defect density and a second portion having a second defect density. The first defect density is greater than the second defect density. An insulating material is disposed over the first portion. The insulating material is not formed on or is removed from the second portion.

A method according to embodiments of the invention includes growing a III-nitride semiconductor structure on a GaN substrate. The GaN substrate includes a first portion having a first defect density and a second portion having a second defect density. The first defect density is greater than the second defect density. At least part of the III-nitride semiconductor structure grown over the first portion is electrically isolated from part of the III-nitride semiconductor structure grown over the second portion.

Embodiments of the invention include a III-nitride semiconductor layer including a first portion having a first defect density and a second portion having a second defect density. The first defect density is greater than the second defect density. An electrical isolation element is disposed in the III-nitride semiconductor layer in the first portion, wherein the electrical isolation element electrically isolates the first portion from at least part of the second portion.

### BRIEF DESCRIPTION OF THE DRAWINGS

FIG. 1 is a cross sectional view of a portion of a GaN substrate on which a device structure is grown.

FIG. 2 illustrates a top view of the structure illustrated in FIG. 1.

FIG. 3 illustrates the structure of FIG. 1 after forming electrically insulating covers over the defect centers.

FIG. 4 illustrates a top view of the structure illustrated in FIG. 3.

FIG. 5 is a cross sectional view of a diode including electrically insulating covers over the defect centers.

FIG. 6 is a cross sectional view of a portion of a GaN substrate on which a device structure is grown, after removing a portion of the defect centers.

FIG. 7 is a cross sectional view of a diode including etched defect centers.

FIG. 8 is a top view of an electrically insulating cover including alignment features.

FIG. 9 is a cross sectional view of a portion of a device structure with implanted defect centers.

### DETAILED DESCRIPTION

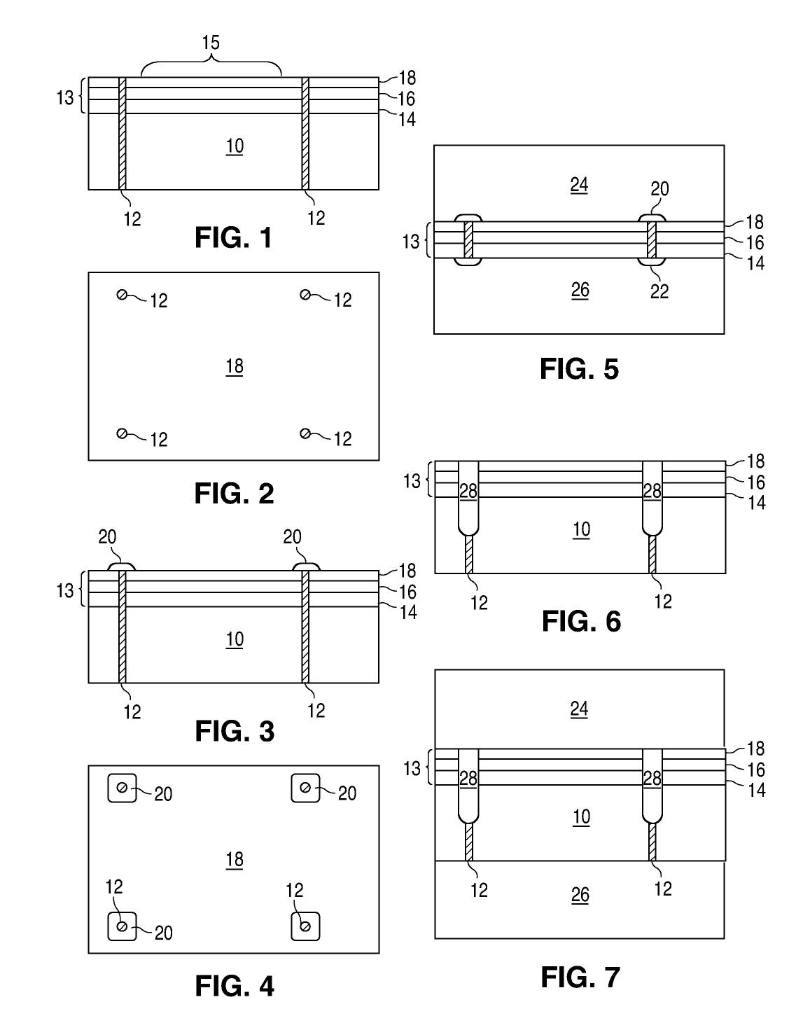

FIG. 1 illustrates a device structure 13 grown over a portion of a GaN substrate 10 including defect centers 12. Though in the examples below substrate 10 is a GaN substrate, embodiments of the invention may be applied to other substrates that include defect centers, including, for example, other III-nitride substrates including ternary substrates such as InGaN or AlGaN or quaternary substrates, and other III-V substrates. In addition, though in the examples below the defect centers 12 are point defect centers, embodiments of the invention may be applied to substrates including defect centers of any shape including line defect centers. In the top view illustrated in FIG. 2, defect centers 12 are formed in a square lattice array. Embodiments of the invention cover any suitable arrangement of defect centers.

GaN substrates 10 including point defect centers 12 are commercially available. The spacing between neighboring defect centers 12 is controlled by the substrate manufacturer. Typical spacing is on the order of 1 mm. The layers in the device structure 13 grown over substrate 10 replicate the material quality in different regions of substrate 10. Accordingly, in device structure 13, material grown over defect centers 12 has a high concentration of defects, for example 10⁶ cm⁻² or more. Material 15 grown between defect centers 12 has a much lower concentration of defects, for example 10⁴ cm⁻² or less. In some embodiments, the material 15 between defect centers 12 has a concentration of defects at least two orders of magnitude less than defect centers 12.

Ideally, devices are confined to the spaces 15 between defect centers 12. However, the size of devices in some embodiments necessarily includes at least one defect center 12. For example, devices may be at least 3 mm in length in some embodiments, at least 4 mm in length in some embodiments, and at least 10 mm in length in some embodiments. Such devices cannot be confined to the spaces 15 between defect centers 12, when the defect centers are spaced 1 mm apart.

In devices that include a defect center 12, due to the high concentration of defects at defect center, forming a metal contact or other conductive region in direct contact with defect center 12 can cause a short. Embodiments of the invention are directed to structures and methods that electrically isolate defect centers 12 such that metal contacts can be formed over defect centers 12.

In some embodiments, a device structure 13 is first grown over a substrate 10 including defect centers 12. Though in the examples below, the device structure 13 is a diode, embodiments of the invention may be applied to any suitable device structure including but not limited to other electronic and optoelectronic devices including field effect transistors, high electron mobility transistors, light emitting diodes, and lasers. The device structure 13 often includes different layers of different composition, dopant type, and dopant concentration. For example, device structure 13 generally includes both p- and n-type layers, and may include, for example, GaN, InGaN, and/or AlGaN layers.

As described above, in the structure illustrated in FIG. 1, the device structure 13 is a diode. Device structure 13 includes a highly doped n-type GaN layer 14, a less highly doped n-type GaN layer 16, and a p-type GaN layer 18. FIG. 2 is a top view of a portion of a wafer on which a device structure is grown. Though a wafer will typically include many defect centers depending on the size of the wafer and the spacing of the defect centers, four defect centers 12 are illustrated in FIG. 2.

In the structure illustrated in FIG. 3, an insulating cover 20 is formed on the top surface of device structure 13, over each defect center 12. FIG. 4 is a top view of the structure illustrated in FIG. 3. Though square covers 20 are illustrated in FIG. 4, any suitable shape may be used. Insulating cover 20 may be a dielectric material, an oxide of silicon such as SiO₂, a nitride of silicon such as Si₃N₄, an oxynitride of silicon, a metal oxide, a multi-layer structure including any of the above-described materials, a multi-layer structure including one or more metal layers sandwiched between insulating materials, or any other suitable material. Covers 20 are thick enough to prevent shorting, but as thin as possible to avoid creating a large step. Covers 20 are between 100 Å and 10 μm thick in some embodiments, between 0.1 and 0.5 μm thick in some embodiments, and between 0.1 and 0.3 μm thick in some embodiments. Covers 20 are wide enough to completely cover the defect center in order to prevent shorting. Point defect centers are often on the order of tens of microns wide, for example between 10 and 100 μm wide in some embodiments and between 50 and 100 μm wide in some embodiments. Covers 20 may be 50% wider than the defect centers in some embodiments, 20% wider than the defect centers in some embodiments, and 10% wider than the defect centers in some embodiments.

Covers 20 may be formed by depositing a dielectric layer over the entire surface of device structure 13 by any suitable technique including deposition, plasma-enhanced chemical vapor deposition, and sputtering. The dielectric layer is then patterned by masking and etching the layer with conventional photolithography. Since the spacing between defect centers is known (because it is determined during manufacture of the substrate), the mask used to pattern the dielectric layer can be aligned with all the defect centers by aligning the mask with a single defect center, for example by simple visual alignment of the mask with the wafer. Covers 20 may be aligned with defect centers 12 to within 10 μm.

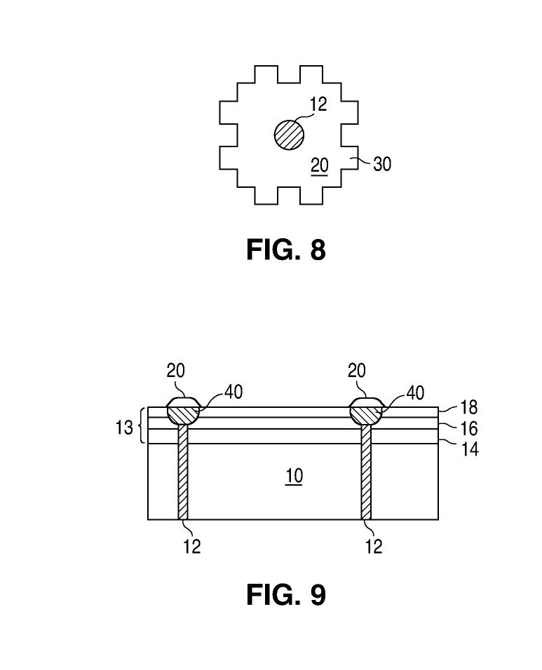

In some embodiments, covers 20 are formed with fine alignment features to aid in the alignment of later photolithography masks, as illustrated in FIG. 8. The cover 20 illustrated in FIG. 8 includes projections 30 on the sides of a nominally square cover 20. Projections 30 may be used for alignment of a mask. Projections 30 may be on the order of a few microns wide. Projections 30 may be between 0.05 and 10 μm wide in some embodiments, between 0.5 and 8 μm wide in some embodiments, and between 1 and 5 μm wide in some embodiments.

FIG. 5 illustrates the structure of FIG. 3 formed into a finished device. In any of the embodiments described herein, substrate 10 may remain part of the final device as illustrated in FIG. 6, may be thinned as illustrated in FIG. 5, or may be removed from the device structure 13. In the structure illustrated in FIG. 5, a metal anode 24 is formed on the p-type region 18. Covers 22 are formed over the bottoms of defect centers 12, for example by following the procedure described above in reference to FIGS. 3 and 4 on the bottom of the substrate 10. A metal cathode 26 is formed on the bottom of substrate 10, which may be n-type. Anode 24 touches the semiconductor structure 13 in the regions between covers 20. Similarly, cathode 26 touches substrate 10 if present, or the bottom of n-type region 14 if the substrate is removed, in the regions between covers 22.

FIGS. 6 and 7 illustrate electrically isolating defect centers 12 by etching away all or a portion of the defect center to form a hole 28 in the semiconductor. FIG. 6 illustrates the structure of FIG. 1 after masking then etching away portions of defect centers 12, leaving semiconductor structure 13 between the etched regions. The depth of etched regions 28 depends on the device structure. In some embodiments, etched regions 28 extend through the entire thickness of the device structure or the entire thickness of the semiconductor structure, including the substrate. In the diode semiconductor structure 13 illustrated in FIG. 6, the defect centers must be etched away at least through the entire thickness of p-type region 18, to avoid shorting. In FIG. 6, the etched regions extend through the entire thickness of p-type region 18, through the entire thickness of n-type region 16, through the entire thickness of n-type region 14, and into substrate 10.

Etched regions 28 may be as wide as or wider than defect centers 12 in order to avoid shorting. Etched regions 28 may be 50% wider than the defect centers in some embodiments, 20% wider than the defect centers in some embodiments, and 10% wider than the defect centers in some embodiments. Etched regions 28 may be between 100 Å and 100 μm deep in some embodiments, between 50 nm and 30 μm deep in some embodiments, and between 0.1 and 0.3 μm deep in some embodiments.

In FIG. 7, a metal anode 24 and metal cathode 26 are formed on p-type region 18 and substrate 10, respectively. Anode 24 is formed such that metal does not fill etched regions 28. Air or other ambient gas may be trapped in etched regions 28. In some embodiments, a solid electrically insulating material such as any of the insulating materials described above is formed in etched regions 28 before forming anode 24. For example, to provide structural integrity to a structure formed over etched regions 28, etched regions 28 may be filled with insulating material, including, for example, benzocyclobutene (BCB), polyimide, glass formed by any suitable technique including spinning on, oxides, and nitrides.

FIG. 9 illustrates electrically isolating defect centers 12 from the lower defect density material surrounding them by implanting the defect centers 12. In order to implant defect centers 12, a layer of masking material may be formed over the top surface of the wafer, then an opening in the masking material is formed at each defect center 12 to be implanted. As described above, point defect centers are often on the order of tens of microns wide, for example between 10 and 100 μm wide in some embodiments and between 50 and 100 μm wide in some embodiments. In order to make sure the defect center is totally isolated from the surrounding material, the implanted region 40 is typically wider than the defect center. For example, implanted regions 40 may be 50% wider than the defect centers 12 in some embodiments, 20% wider than the defect centers 12 in some embodiments, and 10% wider than the defect centers 12 in some embodiments.

The implant depth depends on the implant conditions, including, for example, the implant species, the implant dose, and the implant energy. The implant regions may extend from the surface of the wafer to a depth of 10 nm in some embodiments, from the surface of the wafer to a depth of 100 nm in some embodiments, and from the surface of the wafer to a depth of 500 nm in some embodiments. Examples of suitable implant species include any suitable p-type species which may act as electrical blocking layers, including, for example, Mg and Be; any suitable inert species including, for example, Ar, N₂, H₂, O₂; any suitable deep acceptor which may act as a traps, including, for example, Fe, Zn, Ni, and Co.

In some embodiments, implanting is combined with other methods of electrical isolation, such as the insulating covers described above. In some embodiments, defect centers on both the top surface and the bottom surface of the wafer may be implanted, as necessary for the particular device grown on the wafer.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

What is being claimed is:

1. A structure comprising:
a III-nitride semiconductor layer comprising a first portion having a first defect density and a second portion having a second defect density, wherein the first defect density is greater than the second defect density; and
an insulating material disposed over the first portion and not formed on or removed from the second portion.

2. The structure of claim 1 further comprising a metal layer disposed over the first portion and the second portion, wherein the insulating material is disposed between the first portion and the metal.

3. The structure of claim 2 wherein the metal layer is in direct contact with the second portion.

4. The structure of claim 1 wherein the first defect density is at least two orders of magnitude greater than the second defect density.

5. The structure of claim 1 wherein the insulating material is wider than the first portion.

6. The structure of claim 1 wherein the insulating material has a thickness between 100 Å and 10 μm.

7. The structure of claim 1 wherein the insulating material comprises an alignment feature.

8. The structure of claim 1 further comprising an implanted region formed in part of the first portion.

9. The structure of claim 8 wherein the implanted region is implanted with one of a p-type species, Mg, Be, an inert species, Ar, N₂, H₂, O₂, a deep acceptor species, Fe, Zn, Ni, and Co.

10. A method comprising:
growing a III-nitride semiconductor structure on a GaN substrate, the GaN substrate comprising a first portion having a first defect density and a second portion having a second defect density, wherein the first defect density is greater than the second defect density;
electrically isolating at least part of the III-nitride semiconductor structure grown over the first portion from part of the III-nitride semiconductor structure grown over the second portion.

11. The method of claim 10 wherein electrically isolating comprises forming a hole in at least part of the III-nitride semiconductor structure grown over the first portion.

12. The method of claim 11 wherein the hole is surrounded by material with a lower defect density than the first defect density.

13. The method of claim 11 wherein the hole is disposed over material having the first defect density.

14. The method of claim 11 wherein the hole is wider than the first portion.

15. The method of claim 11 wherein:
the III-nitride semiconductor structure comprises a p-type layer and an n-type layer; and
the hole extends through an entire thickness of the p-type layer.

16. The method of claim 11 further comprising disposing a metal layer over the III-nitride semiconductor structure such that the metal layer is not disposed on the sidewalls and bottom of the hole.

17. The method of claim 11 further comprising:
filling the hole with a solid insulating material; and
after filling the hole, disposing a metal layer over the III-nitride semiconductor structure.

18. The method of claim 10 wherein electrically isolating comprises implanting at least part of the III-nitride semiconductor structure grown over the first portion with at least one implant species, wherein at least part of the III-nitride semiconductor structure grown over the second portion is not implanted.

19. The method of claim 18 wherein the implant species comprises one of a p-type species, Mg, Be, an inert species, Ar, N₂, H₂, O₂, a deep acceptor species, Fe, Zn, Ni, and Co.

20. The method of claim 18 wherein the implanted part is wider than the first portion.

21. The method of claim 10 wherein electrically isolating comprises disposing an insulating material over at least part of the III-nitride semiconductor structure grown over the first portion, wherein the insulating material is not disposed on or is removed from at least part of the III-nitride semiconductor structure grown over the second portion.

22. A structure comprising:
a III-nitride semiconductor layer comprising a first portion having a first defect density and a second portion having a second defect density, wherein the first defect density is greater than the second defect density; and
an electrical isolation element disposed in the III-nitride semiconductor layer in the first portion, wherein the electrical isolation element electrically isolates the first portion from at least part of the second portion.

23. The structure of claim 22 wherein the electrical isolation element is a hole formed in the III-nitride semiconductor layer, wherein the hole is disposed over part of the first portion.

24. The structure of claim 23 wherein the hole is filled with a solid insulating material.

25. The structure of claim 22 wherein the electrical isolation element is an implanted region formed in part of the first portion.
